(19) United States
(12) Patent Application Publication
(10) Pub. No.: US 2026/0168092 A1
(43) Pub. Date: Jun. 18, 2026

(54) METHOD OF DEPOSITING A RARE EARTH METAL OXIDE FILM

(71) Applicant: ASM IP Holding B.V., Almere (NL)

(72) Inventors: Rishabh Rastogi, Chandler, AZ (US); Ren-Jie Chang, Chandler, AZ (US); Fu Tang, Gilbert, AZ (US); Petri Raisanen, Gilbert, AZ (US); Jereld Lee Winkler, Gilbert, AZ (US)

(21) Appl. No.: 19/415,927

(22) Filed: Dec. 11, 2025

Related U.S. Application Data
(60) Provisional application No. 63/734,381, filed on Dec. 16, 2024.

(51) Int. Cl. C23C 16/455; C23C 16/40; C23C 16/52; H10D 64/68; H10P 14/60; H10P 14/692

(52) U.S. Cl. CPC C23C 16/45529; C23C 16/403; C23C 16/405; C23C 16/45544; C23C 16/45553; C23C 16/52; H10D 64/691; H10P 14/6339; H10P 14/69392; H10P 14/69396

(57) ABSTRACT

A substrate processing method for forming a rare earth metal oxide film includes providing a substrate in a reaction chamber and performing a rare earth metal oxide deposition cycle. The rare earth metal oxide deposition cycle includes pulsing a rare earth metal precursor and pulsing a reactant into the reaction chamber.

### CROSS-REFERENCE TO RELATED APPLICATIONS

This application is a nonprovisional of, and claims priority to and the benefit of, U.S. Provisional Patent Application No. 63/734,381 , filed Dec. 16, 2024 and entitled “METHOD OF DEPOSITING A RARE EARTH METAL OXIDE FILM,” which is hereby incorporated by reference herein.

### FIELD

Examples are described that relate to a method for depositing a rare earth metal oxide film, as well as a structure comprising the rare earth metal oxide film and a substrate processing apparatus for depositing the rare earth metal oxide film.

### BACKGROUND

The scaling of semiconductor devices has led to significant improvements in speed and density of integrated circuits. However, there exists a need for more precise deposition techniques and materials to produce semiconductor devices with desirable properties.

Dipole layers may be used to form gates in certain semiconductor devices. Rare earth metal oxides may have desirable properties for certain dipole layers. However, conventional techniques for depositing rare earth metal oxide films may produce films with relatively high levels of unwanted impurities, which may cause undesirable electrical properties. Further, conventional techniques in the formation of rare earth metal oxides may cause unwanted oxidation of surrounding structures. Thus, there exists a desire for techniques to produce rare earth metal oxides, such as rare earth metal oxides in dipole layers, with low impurity levels and minimal unwanted oxidation of surrounding structures.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide a substrate processing method, substrate processing apparatus, and a structure on a substrate. Various examples of the substrate processing method provide for the deposition of a rare earth metal oxide film. Exemplary methods disclosed herein provide rare earth metal oxide films with desired properties, such as low levels of impurities in the film compositions; with exemplary methods can do so efficiently, precisely, and accurately. The exemplary methods disclosed herein provide techniques for the formation and integration of rare earth metal oxides into dipole layers, which may be used in gate structures.

In accordance with various embodiments of the disclosure, a method for depositing a rare earth metal oxide film is provided, the method including: providing a substrate including a surface in a reaction chamber including a reaction space; and performing at least one rare earth metal oxide deposition cycle to deposit the rare earth metal oxide film, wherein the rare earth metal oxide deposition cycle includes: pulsing a rare earth metal precursor to the reaction space, wherein the rare earth metal precursor includes a rare earth metal, and wherein the rare earth metal precursor includes a metalorganic precursor, and pulsing a reactant to the reaction space, wherein the reactant includes an oxidant including one or more of H₂O, hydrogen peroxide, or N₂O.

In some embodiments, the rare earth metal precursor includes a formamidinate.

In some embodiments, the rare earth metal precursor includes tris(N,N′-di-i-propylformamidinato)lanthanum(III).

In some embodiments, the reactant includes H₂O.

In some embodiments, the reactant consists of H₂O and, optionally, an inert/carrier gas.

In some embodiments, the surface includes one or more of a silicon oxide, a silicon nitride, or a silicon oxynitride, and the rare earth metal oxide film is deposited on one or more of the silicon oxide, the silicon nitride, or the silicon oxynitride.

In some embodiments, the method further includes depositing a transition metal oxide on the rare earth metal oxide film.

In some embodiments, the transition metal oxide includes hafnium oxide.

In some embodiments, the rare earth metal oxide film has a thickness less than 15 Angstroms.

In some embodiments, the surface includes one or more of a silicon oxide, a silicon nitride, or a silicon oxynitride, a first hafnium oxide film is deposited on one or more of the silicon oxide, the silicon nitride, and the silicon oxynitride, and the rare earth metal oxide film is deposited on the first hafnium oxide film.

In some embodiments, a second hafnium oxide film is deposited on the rare earth metal oxide film.

In some embodiments, the reactant includes H₂O.

In some embodiments, the method further includes repeating the rare earth metal oxide deposition cycles at least 20 times, wherein a periodic aluminum oxide cycle is performed once after between about 10 to about 20 rare earth metal deposition cycles, wherein the periodic aluminum oxide cycle includes: removing the substrate from the reaction chamber, after removing the substrate from the reaction chamber, pulsing an aluminum precursor onto a surface of the reaction space, pulsing an oxygen reactant onto the surface of the reaction space to form an aluminum oxide on the surface of the reaction space, and after pulsing the oxygen reactant, reintroducing the substrate into the reaction chamber.

In some embodiments, the method is a thermal process.

In some embodiments, the reactant does not include O₂ or O₃.

In some embodiments, the method further includes annealing the rare earth metal oxide film, wherein a temperature during annealing is less than about 600° C.

In some embodiments, the rare earth metal oxide film has a carbon at. % less than 10 at. %.

In some embodiments, a temperature during the step of performing at least one rare earth metal oxide deposition cycle is between about 150° C. and about 350° C., and a pressure during the step of performing at least one rare earth metal oxide deposition cycle is between about 0.5 torr and about 10 torr.

In accordance with various embodiments of the disclosure, a method for forming a gate structure is provided, the method including: providing a substrate including a surface in a reaction chamber; and performing at least one lanthanum oxide deposition cycle to form a lanthanum oxide film, wherein the lanthanum oxide deposition cycle includes: pulsing a lanthanum precursor, wherein the lanthanum precursor includes tris(N,N′-di-i-propylformamidinato)lanthanum(III), and pulsing a reactant into the reaction chamber, wherein the reactant includes H₂O, and wherein the reactant does not include O₂ or O₃.

In accordance with various embodiments of the disclosure, a system for depositing a rare earth metal oxide film is provided, the system including: a reaction chamber; a susceptor in the reaction chamber configured to hold a substrate; a rare earth metal precursor source configured to provide a rare earth metal precursor into the reaction chamber, wherein the rare earth metal precursor includes a rare earth metal, and wherein the rare earth metal precursor includes a metalorganic precursor; a reactant source configured to provide a reactant into the reaction chamber, wherein the reactant includes at least one of H₂O, hydrogen peroxide, or N₂O; and a controller including an addressable storage medium, wherein the controller is configured to control gas flow into the reaction chamber, a temperature of the reaction chamber, a pressure of the reaction chamber, and a movement of the substrate to: provide the substrate on the susceptor, and performing at least one rare earth metal oxide deposition cycle, wherein the rare earth metal oxide deposition cycle includes: pulsing the rare earth metal precursor, and pulsing the reactant into the reaction chamber.

According to one or more embodiments, a method for the depositing a rare earth metal oxide film is provided. An exemplary method includes providing a substrate in a reaction chamber comprising a reaction space. An exemplary method can further include performing at least one rare earth metal oxide deposition cycle. In some embodiments, the rare earth metal deposition cycle comprises pulsing a rare earth metal precursor to the reaction space and pulsing a reactant to the reaction space. In some embodiments, the rare earth metal deposition cycle is a cyclical deposition process, such as an atomic layer deposition (ALD) process.

The rare earth metal precursor comprises at least one rare earth metal. In some embodiments, the rare earth metal precursor comprises lanthanum. In some embodiments, the rare earth metal precursor comprises a metalorganic precursor. In some embodiments, the rare earth metal precursor comprises an amidinate. In some embodiments, the rare earth metal precursor comprises a formamidinate. In some embodiments, the rare earth metal precursor comprises tris(N,N′-di-i-propylformamidinato)lanthanum(III).

In some embodiments, the reactant comprises an oxidant. In some embodiments, the oxidant comprises one or more of H₂O, hydrogen peroxide, N₂O, O₂, or O₃, in any combination. In some embodiments the reactant does not comprise O₂ or O₃. In some embodiment, the reactant comprises H₂O.

In an exemplary embodiment, the rare earth metal precursor comprises tris(N,N′-di-i-propylformamidinato)lanthanum(III) and the reactant comprises H₂O.

In some embodiments, the rare earth metal oxide deposition cycle is repeated a plurality of times. In some embodiments, the rare earth metal oxide deposition cycle is repeated at least 10, or at least 20 times. In some embodiments where the rare earth metal oxide deposition cycle is repeated, a periodic aluminum oxide cycle is performed after between about 10 to about 20 rare earth metal deposition cycles.

In some embodiments, the periodic aluminum oxide cycle comprises removing the substrate from the reaction space or reaction chamber. The periodic aluminum oxide cycle continues after removing the substrate from the reaction space with pulsing an aluminum precursor onto a surface of the reaction space. In some embodiments, the periodic aluminum oxide cycle further includes pulsing an oxygen reactant onto the surface of the reaction space to form an aluminum oxide on the surface of the reaction space. In some embodiments, the periodic aluminum oxide cycle continues after pulsing the oxygen reactant with reintroducing the substrate into the reaction space or reaction chamber. In some embodiments, after a periodic aluminum oxide cycle, the at least one rare earth metal oxide deposition cycle is performed.

In some embodiments, the rare earth metal deposition cycle is a thermal process. In some embodiments, the substrate is not exposed to a plasma during the rare earth metal deposition cycle. In some embodiments, the substrate processing method is a thermal process.

In accordance with further examples of the disclosure, a device is formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method in accordance with one or more embodiments of the disclosure;

FIG. 2 illustrates a rare earth metal oxide deposition cycle in accordance with one or more embodiments of the disclosure;

FIG. 3 illustrates a periodic aluminum oxide cycle in accordance with one or more embodiments of the disclosure;

FIG. 4 illustrates an example of a substrate processing apparatus in accordance with one or more examples of the disclosure;

FIG. 5 illustrates an example of a structure that form part of a device in accordance with one or more examples of the disclosure;

FIG. 6 illustrates another example of a structure that form part of a device in accordance with one or more examples of the disclosure;

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “overlying” can refer to two films in direct contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

As used herein, “rare earth metal” comprises scandium, yttrium, lanthanides (lanthanum, cerium, praseodymium, neodymium, promethium, samarium, europium, gadolinium, terbium, dysprosium, holmium, erbium, thulium, ytterbium, and lutetium), and actinides (actinium, thorium, protactinium, uranium, neptunium, plutonium, americium, curium, berkelium, californium, einsteinium, fermium, mendelevium, nobelium, and lawrencium).

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, in some embodiments. Further, in this disclosure, the terms “comprising,” “including,” “constituted by” and “having,” or the like, can refer independently to “typically or broadly comprising,” “comprising,” “consisting essentially of,” or “consisting of” in some embodiments. In this disclosure, any defined meanings do not necessarily exclude ordinary and customary meanings in some embodiments.

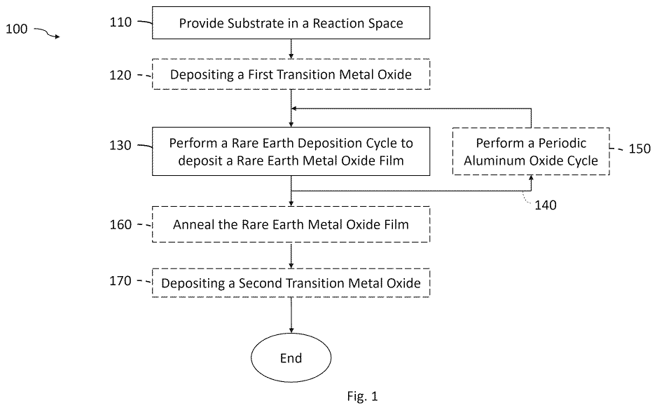

FIG. 1 illustrates a method 100 of depositing a rare earth metal oxide film on a substrate in accordance with exemplary embodiments of the disclosure. In some embodiments, the method 100 may be used to form a dipole layer. In some embodiments, the dipole layer is formed using a ‘dipole-first’ approach. In some embodiments, the dipole layer is formed using a ‘dipole-last’ approach. In some embodiments, the dipole layer is formed using a ‘dipole-middle’ approach.

Method 100 includes the step of providing a substrate within a reaction space of a reaction chamber (step 110), optionally depositing a first transition metal oxide film (step 120), performing a rare earth deposition cycle to deposit a rare earth metal oxide film (step 130), optionally repeating the step of performing the rare earth metal oxide deposition cycle (loop 140), optionally performing a periodic aluminum oxide cycle (step 150), optionally annealing the rare earth metal oxide film (step 160), and, optionally, depositing a second transition metal oxide film (step 170).

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

In some embodiments, the substrate comprises a surface that comprises one or more of a silicon oxide, a silicon nitride, or a silicon oxynitride. In other embodiments, the surface comprises a transition metal oxide, such as hafnium oxide. In other embodiments, the surface comprises a transition metal oxide, such as hafnium oxide, overlying one or more of a silicon oxide, a silicon nitride, or a silicon oxynitride.

During step 110, the substrate can be brought to a desired temperature and/or the reaction space can be brought to a desired pressure, such as a temperature and/or pressure suitable for subsequent steps. By way of examples, a temperature (e.g., of a substrate or a substrate support) within a reaction space can be between about 150° C. and about 350° C., or between about 200° C. and about 300° C., or between about 230° C. and about 270° C. By way of examples, a pressure within a reaction space can be less than or equal to 10 torr, or between about 0.5 torr and 10 torr, or between about 2 torr and about 6 torr.

The method 100 continues, optionally, with depositing a first transition metal oxide film on the substrate. In some embodiments, the first transition metal oxide film is deposited on one or more of a silicon oxide, a silicon nitride, or a silicon oxynitride of a substrate surface. The transition metal oxide may be deposited by any suitable method, including a cyclical deposition process. In some embodiments, the first transition metal oxide film comprises one or more of hafnium, zirconium, niobium, titanium, vanadium, tungsten, molybdenum, or tantalum. In some embodiments, the first transition metal oxide film has a thickness between about 5 Angstroms and about 30 Angstroms, or between about 13 Angstroms and about 20 Angstroms.

The method 100 continues with performing a rare earth metal oxide deposition cycle to deposit a rare earth metal oxide film. In some embodiments, the rare earth metal oxide is a cyclical deposition process, such as a cyclic chemical vapor deposition (CCVD), or an atomic layer deposition (ALD) process. In some embodiments, the rare earth metal oxide film is deposited directly on a transition metal oxide film. In some embodiments where a first transition metal oxide film is deposited, the rare earth metal oxide film may be deposited directly on the first transition metal oxide film. In some embodiments, a temperature (e.g., of a substrate or a substrate support) within a reaction space during performing a rare earth metal oxide deposition cycle can be between about 150° C. and about 350° C., or between about 200° C. and about 300° C., or between about 230° C. and about 270° C. In some embodiments, a pressure within a reaction space during performing a rare earth metal oxide deposition cycle can be less than or equal to 10 torr, or between about 0.5 torr and 10 torr, or between about 2 torr and about 6 torr.

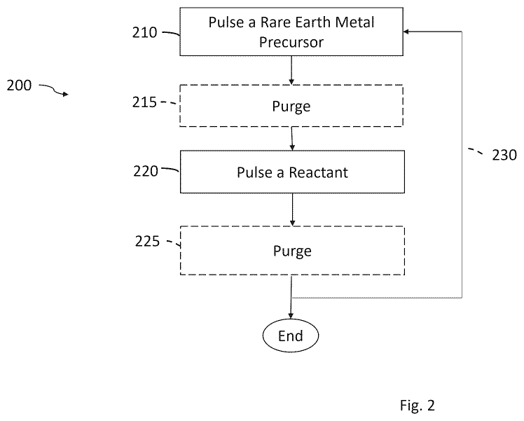

FIG. 2 illustrates a method 200 suitable for step 130 in FIG. 1. Method 200 includes a step of pulsing a rare earth metal precursor 210 to the reaction space and a step of pulsing a reactant 220 to the reaction space. Method 200 can also include an optional purge step 215 after the step of pulsing a rare earth metal precursor 210 and/or an optional purge step 225 after the step of pulsing a reactant 220. The optional purge steps 215 and 225 may remove gases, precursors, reactants, and/or by-products from the reaction space. As illustrated, method 200 can include repeating the rare earth metal oxide cycle (loop 230) a desired number of times. In some embodiments, the rare earth metal oxide cycle can comprise pulsing the reactant 220 performed before the pulsing the rare earth metal precursor 210. In some embodiments, a rare earth metal oxide cycle can comprise any substep 210, 215, 220, or 225 repeated a plurality of times. In some embodiments, the steps of pulsing a rare earth metal precursor 210 and pulsing a reactant 220 may at least partially overlap in time.

The rare earth metal precursor comprises a rare earth metal. In some embodiments, the rare earth metal comprises lanthanum. In some embodiments, the rare earth metal precursor comprises a metalorganic precursor. In some embodiments, the rare earth metal precursor comprises an amidinate. In some embodiments, the rare earth metal precursor comprises a formamidinate. In some embodiments, the rare earth metal precursor comprises tris(N,N′-di-i-propylformamidinato)lanthanum(III).

In some embodiments, the reactant comprises an oxidant. In some embodiments, the oxidant comprises one or more of H₂O, hydrogen peroxide, N₂O, O₂, or O₃, in any combination. In some embodiments the reactant does not comprise O₂ or O₃. In some embodiment, the reactant comprises H₂O.

In an exemplary embodiment, the rare earth metal precursor comprises tris(N,N′-di-i-propylformamidinato)lanthanum(III) and the reactant comprises H₂O. A rare earth metal oxide film deposited using tris(N,N′-di-i-propylformamidinato)lanthanum(III) and H₂O may have low amounts of carbon impurities. In some embodiments, a rare earth metal oxide film deposited using tris(N,N′-di-i-propylformamidinato)lanthanum(III) and H₂O may have an atomic percentage of carbon less than about 10 at %, or less than 5 at %, or less than 1 at %.

Returning to FIG. 1, the method 100 may continue with, optionally, repeating the step of performing the rare earth metal oxide deposition cycle (loop 140). In some embodiments, the rare earth metal oxide deposition cycle is repeated a plurality of times. In some embodiments, the rare earth metal oxide deposition cycle is repeated a plurality of times until the rare earth metal oxide film reaches between about 2 Angstroms and about 15 Angstroms, or between 3 Angstroms and 10 Angstroms, or between about 3 Angstroms and about 5 Angstroms.

In some embodiments, the method 100 includes an optional step of performing a periodic aluminum oxide cycle between performing rare earth metal deposition cycles. In some embodiments where the rare earth metal oxide deposition cycle is repeated, a periodic aluminum oxide cycle is performed after a plurality of rare earth metal deposition cycles. In some embodiments where the rare earth metal oxide deposition cycle is repeated, a periodic aluminum oxide cycle is performed after between about 10 to about 20 rare earth metal deposition cycles.

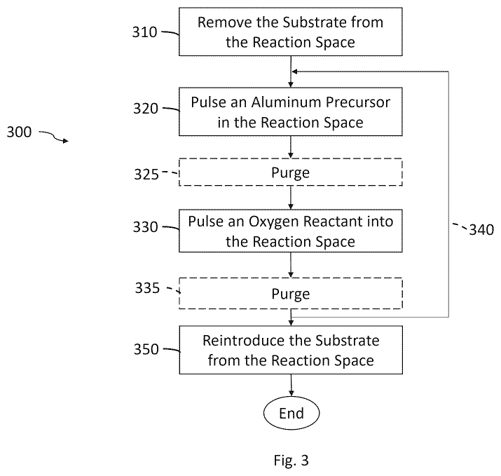

FIG. 3 illustrates a method 300 suitable for step 150 in FIG. 1. In some embodiments, the periodic aluminum oxide cycle comprises removing the substrate from the reaction space and/or reaction chamber. The periodic aluminum oxide cycle continues with pulsing an aluminum precursor onto a surface of the reaction space. In some embodiments, the periodic aluminum oxide cycle further includes pulsing an oxygen reactant onto the surface of the reaction space to deposit an aluminum oxide on the surface of the reaction space. In some embodiments where the periodic aluminum oxide cycle comprises removing the substrate from the reaction space and/or reaction chamber, the periodic aluminum oxide cycle continues after pulsing the oxygen reactant with reintroducing the substrate into the reaction space and/or reaction chamber. In some embodiments, after a periodic aluminum oxide cycle, one or more rare earth metal oxide deposition cycles are performed.

Returning to FIG. 1, the method 100 may continue with, optionally, annealing the rare earth metal oxide film (step 160). In some embodiments, the rare earth metal oxide film is annealed at a temperature between about 550° C. and about 950° C. or between about 600° C. and 750° C.

The method 100 may continue with depositing a second transition metal oxide film on the substrate (step 170). The second transition metal oxide film may be deposited by any suitable method, including a cyclical deposition process. In some embodiments, the second transition metal oxide film comprises one or more of hafnium, zirconium, niobium, titanium, vanadium, tungsten, molybdenum, or tantalum. In some embodiments, the second transition metal oxide film has a thickness between about 5 Angstroms and about 30 Angstroms, or between about 13 Angstroms and about 20 Angstroms. In some embodiments, the second transition metal oxide film is deposited directly on the rare earth metal oxide film. In some embodiments, a temperature (e.g., of a substrate or a substrate support) within a reaction space during depositing a second transition metal oxide film can be between about 150° C. and about 350° C., or between about 200° C. and about 300° C., or between about 230° C. and about 270° C. In some embodiments, a pressure within a reaction space during depositing a second transition metal oxide film can be less than or equal to 10 torr, or between about 0.5 torr and 10 torr, or between about 2 torr and about 6 torr.

In some embodiments, the step of annealing 160 may be performed after depositing the second transition metal oxide 170. In some embodiments, the step of annealing 160 may be performed before depositing the second transition metal oxide 170.

Additionally, a carrier and/or inert gas can be co-flowed throughout method 100 or during any of the sub-steps of method 100. By way of example, a carrier and/or an inert gas can be one or more of helium, argon, or nitrogen.

Some embodiments of method 100 may produce a dipole layer comprising the rare earth metal oxide. In some embodiments, the dipole layer has a thickness of about 8 Angstroms to about 30 Angstroms. In embodiments where no first transition metal oxide film is formed or the rare earth metal oxide is formed on a silicon oxide, silicon nitride, or silicon oxynitride (underlying the rare earth metal oxide film), the method may be used in a dipole-first method to form a dipole layer. In embodiments where the rare earth metal oxide is formed on a transition metal oxide and no second transition metal oxide film is formed, the method may be used in a dipole-last method to form a dipole layer. In embodiments where the rare earth metal oxide is formed on and/or overlying a transition metal oxide and a second transition metal oxide film is formed on and/or overlying the rare earth metal oxide, the method may be used in a dipole-middle method to form a dipole layer.

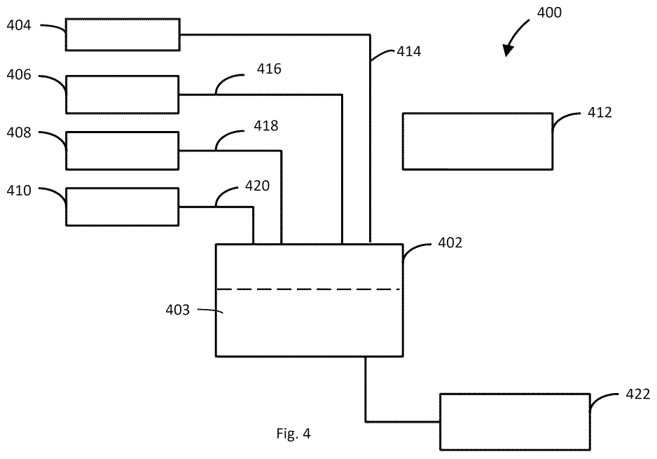

FIG. 4 illustrates an example of a substrate processing apparatus 400 in accordance with one or more examples of the disclosure. Apparatus 400 can be used to perform a method as described herein and/or form a structure or device portion as described herein.

In the illustrated example, apparatus 400 includes one or more reaction chambers 402, a reaction space 403, a rare earth metal precursor gas source 404, an aluminum precursor gas source 406, a first reactant gas source 408, a second oxygen reactant gas source 410, an exhaust source 422, and a controller 412.

Reaction chamber 402 can include any suitable reaction chamber, such as an atomic layer deposition (ALD) or chemical vapor deposition (CVD) reaction chamber.

Rare earth metal precursor gas source 404 can include a vessel and one or more rare earth metal precursors as described herein-alone or mixed with one or more carrier (e.g., inert) gases. Aluminum precursor gas source 406 can include a vessel and one or more metal precursors as described herein-alone or mixed with one or more carrier (e.g., inert) gases. Reactant gas source 408 can include a vessel and one or more reactants as described herein- alone or mixed with one or more carrier gases. Second oxygen reactant gas source 410 can include one or more oxygen reactant gases as described herein. Although illustrated with four gas sources 404-410, apparatus 400 can include any suitable number of gas sources. Gas sources 404-410 can be coupled to reaction chamber 402 via lines 414-420, which can each include flow controllers, valves, heaters, and the like.

Exhaust source 422 can include one or more vacuum pumps.

Controller 412 includes electronic circuitry and software to selectively operate valves, manifolds, heaters, pumps and other components included in the apparatus 400. Such circuitry and components operate to introduce precursors, reactants, and gases from the respective sources 404-410. Controller 412 can control timing of gas pulse sequences, temperature of the substrate and/or reaction chamber, pressure within the reaction chamber, and various other operations to provide proper operation of the apparatus 400. Controller 412 can include control software to electrically or pneumatically control valves to control flow of precursors, reactants and purge gases into and out of the reaction chamber 402. Controller 412 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 400 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 402. Further, as a schematic representation of a system, many components have been omitted for simplicity of illustration, and such components may include, for example, various valves, manifolds, purifiers, heaters, containers, vents, and/or bypasses.

During operation of apparatus 400, substrates, such as semiconductor wafers (not illustrated), are transferred from, e.g., a substrate handling system to reaction chamber 402. Once substrate(s) are transferred to reaction chamber 402, one or more gases from gas sources 404-410, such as precursors, reactants, carrier gases, and/or purge gases, are introduced into reaction chamber 402.

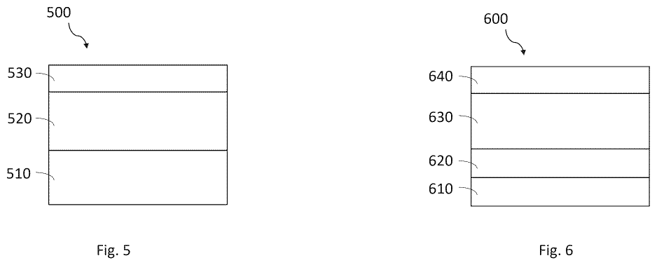

FIG. 5 illustrates a structure/a portion of a device 500 in accordance with additional examples of the disclosure. Device or structure 500 includes a substrate 510, a film comprising a rare earth metal oxide 520, and a film comprising a transition metal oxide 530. In some embodiments, device or structure 500 is at least part of a gate structure. The rare earth metal oxide film 520 may be formed by a method described in this disclosure. In some embodiments, the rare earth metal oxide film 520 is a lanthanum oxide. The rare earth metal oxide film 520 may have a thickness less than 15 Angstroms, less than 10 Angstroms, or between about 3 Angstroms and about 5 Angstroms. The transition metal oxide film 530 may be formed by a method described in this disclosure. In some embodiments, the transition metal oxide film 440 is a hafnium oxide. The transition metal oxide film 530 may have a thickness between about 5 Angstroms and about 30 Angstroms, or between about 13 Angstroms and 20 Angstroms. In some embodiments, the film comprising a transition metal oxide 530 is overlying the film comprising a rare earth metal oxide 520.

FIG. 6 illustrates a structure/a portion of a device 600 in accordance with additional examples of the disclosure. Device or structure 600 includes a substrate 610, a film comprising a first transition metal oxide 640, a film comprising a rare earth metal oxide 630, and a film comprising a second transition metal oxide 640. In some embodiments, device or structure 600 is at least part of a gate structure. The first transition metal oxide film 610 may be formed by a method described in this disclosure. In some embodiments, the first transition metal oxide film 610 is a hafnium oxide. The first transition metal oxide film 610 may have a thickness between about 5 Angstroms and about 30 Angstroms, or between about 13 Angstroms and 20 Angstroms. The rare earth metal oxide film 630 may be formed by a method described in this disclosure. In some embodiments, the rare earth metal oxide film 630 is a lanthanum oxide. The rare earth metal oxide film 630 may have a thickness less than 15 Angstroms, less than 10 Angstroms, or between about 3 Angstroms and about 5 Angstroms. The second transition metal oxide film 640 may be formed by a method described in this disclosure. In some embodiments, the second transition metal oxide film 640 is a hafnium oxide. The second transition metal oxide film 640 may have a thickness between about between about 5 Angstroms and about 30 Angstroms, or between about 13 Angstroms and 20 Angstroms. In some embodiments, the film comprising a second transition metal oxide 640 is overlying the film comprising a rare earth metal oxide 630, and the film comprising a rare earth metal oxide 630 is overlying the film comprising a transition metal oxide 620.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a rare earth metal oxide film, the method comprising:
providing a substrate comprising a surface in a reaction chamber comprising a reaction space; and
performing at least one rare earth metal oxide deposition cycle to deposit the rare earth metal oxide film, wherein the rare earth metal oxide deposition cycle comprises:
pulsing a rare earth metal precursor to the reaction space, wherein the rare earth metal precursor comprises a rare earth metal, and wherein the rare earth metal precursor comprises a metalorganic precursor, and
pulsing a reactant to the reaction space, wherein the reactant comprises an oxidant comprising one or more of H₂O, hydrogen peroxide, or N₂O.

2. The method of claim 1, wherein the rare earth metal precursor comprises a formamidinate.

3. The method of claim 2, wherein the rare earth metal precursor comprises tris(N,N′-di-i-propylformamidinato)lanthanum(III).

4. The method of claim 1, wherein the reactant comprises H₂O.

5. The method of claim 4, wherein the reactant consists of H₂O and, optionally, an inert/carrier gas.

6. The method of claim 1, wherein the surface comprises one or more of a silicon oxide, a silicon nitride, or a silicon oxynitride, and wherein the rare earth metal oxide film is deposited on one or more of the silicon oxide, the silicon nitride, or the silicon oxynitride.

7. The method of claim 1, further comprising depositing a transition metal oxide on the rare earth metal oxide film.

8. The method of claim 7, wherein the transition metal oxide comprises hafnium oxide.

9. The method of claim 7, wherein the rare earth metal oxide film has a thickness less than 15 Angstroms.

10. The method of claim 1, wherein the surface comprises one or more of a silicon oxide, a silicon nitride, or a silicon oxynitride, wherein a first hafnium oxide film is deposited on one or more of the silicon oxide, the silicon nitride, and the silicon oxynitride, and wherein the rare earth metal oxide film is deposited on the first hafnium oxide film.

11. The method of claim 10, wherein a second hafnium oxide film is deposited on the rare earth metal oxide film.

12. The method of claim 3, wherein the reactant comprises H₂O.

13. The method of claim 1, further comprising repeating the rare earth metal oxide deposition cycles at least 20 times, wherein a periodic aluminum oxide cycle is performed once after between about 10 to about 20 rare earth metal deposition cycles, wherein the periodic aluminum oxide cycle comprises:
removing the substrate from the reaction chamber,
after removing the substrate from the reaction chamber, pulsing an aluminum precursor onto a surface of the reaction space,
pulsing an oxygen reactant onto the surface of the reaction space to form an aluminum oxide on the surface of the reaction space, and
after pulsing the oxygen reactant, reintroducing the substrate into the reaction chamber.

14. The method of claim 1, wherein the method is a thermal process.

15. The method of claim 1, wherein the reactant does not comprise O₂ or O₃.

16. The method of claim 1, further comprising annealing the rare earth metal oxide film, wherein a temperature during annealing is less than about 600° C.

17. The method of claim 12, wherein the rare earth metal oxide film has a carbon at. % less than 10 at. %.

18. The method of claim 1, wherein a temperature during the step of performing at least one rare earth metal oxide deposition cycle is between about 150° C. and about 350° C., and wherein a pressure during the step of performing at least one rare earth metal oxide deposition cycle is between about 0.5 torr and about 10 torr.

19. A method for forming a gate structure, the method comprising:
providing a substrate comprising a surface in a reaction chamber; and
performing at least one lanthanum oxide deposition cycle to form a lanthanum oxide film, wherein the lanthanum oxide deposition cycle comprises:
pulsing a lanthanum precursor, wherein the lanthanum precursor comprises tris(N,N′-di-i-propylformamidinato)lanthanum(III), and
pulsing a reactant into the reaction chamber, wherein the reactant comprises H₂O, and wherein the reactant does not comprise O₂ or O₃.

20. A system for depositing a rare earth metal oxide film, the system comprising:
a reaction chamber;
a susceptor in the reaction chamber configured to hold a substrate;
a rare earth metal precursor source configured to provide a rare earth metal precursor into the reaction chamber, wherein the rare earth metal precursor comprises a rare earth metal, and wherein the rare earth metal precursor comprises a metalorganic precursor;
a reactant source configured to provide a reactant into the reaction chamber, wherein the reactant comprises at least one of H₂O, hydrogen peroxide, or N₂O; and
a controller comprising an addressable storage medium, wherein the controller is configured to control gas flow into the reaction chamber, a temperature of the reaction chamber, a pressure of the reaction chamber, and a movement of the substrate to:
provide the substrate on the susceptor, and
performing at least one rare earth metal oxide deposition cycle, wherein the rare earth metal oxide deposition cycle comprises:
pulsing the rare earth metal precursor, and
pulsing the reactant into the reaction chamber.
